(19) United States
(12) Patent Application Publication
(10) Pub. No.: US 2025/0040307 A1
(43) Pub. Date: Jan. 30, 2025

(54) SEMICONDUCTOR LIGHT-EMITTING ELEMENT AND DISPLAY DEVICE

(71) Applicant: LG ELECTRONICS INC., Seoul (KR)

(72) Inventors: Younghak CHANG, Seoul (KR); Sukkoo JUNG, Seoul (KR)

(73) Assignee: LG ELECTRONICS INC., Seoul (KR)

(21) Appl. No.: 18/716,839

(22) PCT Filed: Dec. 5, 2022
(86) PCT No.: PCT/KR2022/019621

§ 371 Date: Jun. 5, 2024

(30) Foreign Application Priority Data
Dec. 6, 2021 (KR) 10-2021-0172690

(51) Int. Cl. H01L 33/38; H01L 25/16; H01L 33/44

(52) U.S. Cl. CPC H01L 33/385; H01L 25/167; H01L 33/44

(57) ABSTRACT

A semiconductor light emitting device includes a light emitting layer, a first electrode below the light emitting layer, a second electrode on the light emitting layer, and a passivation layer surrounding the light emitting layer. The size of the first electrode may be larger than the size of the light emitting layer.

### TECHNICAL FIELD

The embodiment relates to a semiconductor light emitting device and a display device.

### BACKGROUND ART

Large-area displays include liquid crystal displays (LCDs), OLED displays, and Micro-LED displays.

Micro-LED display is a display that uses micro-LED, a semiconductor light emitting device with a diameter or cross-sectional area of 100 μm or less, as a display element.

Because micro-LED displays use micro-LED, a semiconductor light emitting device, as a display device, they have excellent performance in many characteristics such as contrast ratio, response speed, color reproduction rate, viewing angle, brightness, resolution, lifespan, luminous efficiency and luminance.

In particular, the micro-LED display has the advantage of being able to freely adjust the size and resolution and implement a flexible display because the screen may be separated and combined in a modular manner.

However, because large micro-LED displays require more than millions of micro-LEDs, there is a technical problem that makes it difficult to quickly and accurately transfer micro-LEDs to the display panel.

Transfer technologies that have been recently developed include the pick and place process, laser lift-off method, or self-assembly method.

Among these, the self-assembly method is a method in which a semiconductor light emitting device finds its assembly position within a fluid on its own, which is an advantageous method for implementing a large-screen display device.

However, there is still insufficient research on technology for manufacturing displays through self-assembly of micro-LEDs.

In particular, in the case of rapidly transferring millions of semiconductor light emitting devices to a large display in the prior art, the transfer speed may be improved, but there is a technical problem that the transfer error rate may increase and the transfer yield may be lowered.

In related technologies, a self-assembly transfer process using dielectrophoresis (DEP) is being attempted, but there is a problem with a low self-assembly rate due to the non-uniformity of the DEP force.

Typically, the most suitable type for reducing the size (or diameter) of a semiconductor light emitting device is a vertical semiconductor light emitting device.

However, after the vertical semiconductor light emitting device is assembled on the backplane substrate, there is a problem in that it is difficult to make electrical connections to the lower side of the vertical semiconductor light emitting device.

To solve this problem, a method of electrically connecting the side parts of a vertical semiconductor light emitting device was proposed. That is, according to an undisclosed internal technology, as shown in FIG. 1, the passivation layer 3 must be removed so that side part of the lower side of the light emitting layer 2 of the semiconductor light emitting device 1 is exposed. In addition, as the first electrode 4, an ohmic contact layer 6 is placed on the side part of the lower side of the light emitting layer 2 from which the passivation layer 3 has been removed, and a magnetic layer 5 is disposed on the lower side of the light emitting layer 2.

However, it is very difficult to remove the passivation layer 3 so that side part of the lower side of the light emitting layer 2 is exposed. Moreover, it is almost impossible for the light emitting layer 2 from which the passivation layer 3 has been removed to form an ohmic contact layer 6 limited to side part of the lower side. Therefore, there is an urgent need for a method that not only forms the ohmic contact layer 6 on the light emitting layer 2 but also facilitates electrical connection of the ohmic contact layer 6 after self-assembly.

Meanwhile, during self-assembly, the degree to which semiconductor light emitting devices are quickly assembled at the desired location on the backplane substrate is defined as the assembly rate. In this case, the reaction speed of the semiconductor light emitting device to the magnet during self-assembly is very important to improve the assembly rate. For this purpose, as shown in FIG. 1, a magnetic layer 5 is disposed on the lower side of the light emitting layer 2 of the semiconductor light emitting device 1. However, as the size of the semiconductor light emitting device 1 decreases, the size of the magnetic layer 5 also decreases, so there is a problem that the reaction speed of the semiconductor light emitting device 1 to the magnet decreases and the assembly rate decreases. Therefore, even if the size of the semiconductor light emitting device 1 is reduced, a method is urgently needed to ensure that the size of the magnetic layer 5 is the same or rather larger.

Meanwhile, as shown in FIG. 1, when a magnetic layer 5 and an ohmic contact layer 6 are used as the first electrode 4, there is a problem of low light efficiency and luminance due to high light absorption rate. In particular, the red semiconductor light emitting device based on AlGaInP has very low light efficiency compared to the green semiconductor light emitting device or the blue semiconductor light emitting device, and the first electrode 4 causes a further decrease in light efficiency and luminance.

Meanwhile, as shown in FIG. 1, when the first electrode 4 of the semiconductor light emitting device 1 is exposed to the outside, during self-assembly, a polarization phenomenon occurs in the semiconductor light emitting device 1 by the alternating voltage applied to form a DEP force on the backplane substrate. Accordingly, as shown in FIG. 2, an adsorption defect occurs in which numerous semiconductor light emitting devices 1 stick to each other, resulting in an assembly defect in which the semiconductor light emitting device 1 is not properly assembled in the assembly hole 8H of the partition wall 8 on the substrate 7.

### DISCLOSURE

### Technical Problem

The embodiment objects to solve the above-mentioned problems and other problems.

Another object of the embodiment is to provide a semiconductor light emitting device and a display device that may prevent electrical connection failure.

Additionally, another object of the embodiment is to provide a semiconductor light emitting device and a display device that may improve the assembly rate.

Additionally, another object of the embodiment is to provide a semiconductor light emitting device and a display device that may improve light efficiency and brightness.

In addition, another object of the embodiment is to provide a semiconductor light emitting device and a display device that may prevent assembly defects.

The technical objects of the embodiments are not limited to those described in this item and include those that may be understood through the description of the invention.

### Technical Solution

According to one aspect of the embodiment to achieve the above or other purposes, A semiconductor light emitting device includes a light emitting layer; a first electrode below the light emitting layer; a second electrode on the light emitting layer; and a passivation layer surrounding the light emitting layer; and wherein a size of the first electrode may be larger than a size of the light emitting layer.

The first electrode may include a protrusion portion protruding outward from a side part of the light emitting layer.

The first electrode may include an ohmic contact layer below the light emitting layer; a reflection layer below the light emitting layer; and a magnetic layer below the reflection layer;

At least one of the ohmic contact layer, the constant reflection layer, or the magnetic layer may protrude outward from the side part of the light emitting layer.

At least one of the ohmic contact layer, the constant reflection layer, or the magnetic layer may protrude outward from the side part of the passivation layer.

An upper surface of the ohmic contact layer may be in contact with a lower surface of the passivation layer.

An outer sides of each of the ohmic contact layer, the constant reflection layer, and the magnetic layer may be positioned on a same vertical line.

The lower surface of the light emitting layer has a first area and a second area surrounding the first area, the ohmic contact layer may be in contact with the first area, and the reflection layer may be in contact with the second area.

The lower surface of the light emitting layer has a first area and a second area surrounding the first area, the reflection layer may be in contact with the first area, and the ohmic contact layer may be in contact with the second area.

It may include a metal oxide layer surrounding the first electrode. The metal oxide layer may be disposed below the magnetic layer and on sides of each of the ohmic contact layer, the reflection layer, and the magnetic layer.

The upper surface of the light emitting layer has a first area and a second area surrounding the first area, wherein the passivation layer includes: a first passivation layer on the first area; And a second passivation layer on the second area, wherein a thickness of the first passivation layer may be smaller than a thickness of the second passivation layer. The thickness of the first passivation layer may be less than ½ of the thickness of the second passivation layer.

According to another aspect of the embodiment, the display device incudes a backplane substrate with assembly hole; a semiconductor light emitting device in the assembly hole; a connection electrode on a side of the semiconductor light emitting device; an insulating layer in the assembly hole; a first electrode wiring connected to the upper side of the connection electrode; and a second electrode wiring connected to the upper side of the semiconductor light emitting device.

According to another aspect of the embodiment, the display device includes a backplane substrate having first assembly wiring, second assembly wiring, and assembly holes on the first assembly wiring and the second assembly wiring; a semiconductor light emitting device in the assembly hole; a connection electrode on a side of the semiconductor light emitting device; an insulating layer in the assembly hole; and an electrode wiring connected to the upper side of the semiconductor light emitting device; and wherein at least one assembly wiring of the first assembly wiring or the second assembly wiring may be connected to a lower side of the connection electrode.

### Advantageous Effects

The embodiment is as shown in FIGS. 9, 14, 16 and 18, by being disposed below the light emitting layer 150′ of the first electrode 154, the first electrode 154 can be easily formed. Additionally, the first electrode 154 may include a protrusion portion 154a protruding outward from the side part of the light emitting layer 150′. As shown in FIGS. 12, 13, 20 and 21, after the semiconductor light emitting device 150A to 150D equipped with the protrusion portion 154a is assembled in the assembly hole 340H of the backplane substrate, by electrically connecting the connection electrode 370 disposed around the semiconductor light emitting device 150A to 150D within the assembly hole 340H to the protrusion portion 154a of the first electrode 154, electrical connection of the connection electrode 370 may be easy. Additionally, the contact area between the connection electrode 370 and the first electrode 154 may be increased, thereby improving electrical characteristics.

In the embodiment, as shown in FIGS. 9, 14, 16, and 18, the first electrode 154 disposed on the lower side of the light emitting layer 150′ may have a multilayer structure. The first electrode 154 may include an ohmic contact layer 154-1, a reflection layer 154-2, and a magnetic layer 154-3.

Among these, the magnetic layer 154-3 protrudes not only below the light emitting layer 150′ but also outward from the side part of the light emitting layer 150′, thereby increasing the size of the magnetic layer 154-3, so during self-assembly, the reaction speed of the semiconductor light emitting device 150A to 150D to the magnet increases, thereby improving the assembly rate.

Meanwhile, as shown in FIGS. 14 and 16, when the ohmic contact layer 154-1 and reflection layer 154-2 of the first electrode 154 are disposed on the same surface, for example, by being disposed on the lower surface of the light emitting layer 150′, a current concentration effect may be obtained and light reflectance may be increased, thereby improving light efficiency and brightness.

As shown in FIG. 18, the metal oxide layer is arranged to surround the first electrode 154, so that the semiconductor light emitting device 150D may not be adsorbed during self-assembly by the metal oxide layer. In particular, when light from the lighting device 450 is irradiated to the semiconductor light emitting devices 150D during self-assembly, a fluid adsorption layer 500 may be formed on the surface of the metal oxide layer. The fluid adsorption layer 500 may be formed by molecules of a fluid, such as water molecules, adhering to the surface of a metal oxide. Accordingly, even if the fluid adsorption layer 500 prevents the semiconductor light emitting devices 150D from adsorbing each other, and the semiconductor light emitting devices 150D are already adsorbed to form a lump, adsorption of the semiconductor light emitting device 150D is released by the fluid adsorption layer 500, and the semiconductor light emitting devices 150D can be separated. Therefore, during self-assembly, the semiconductor light emitting devices 150D are not adsorbed to each other by the metal oxide and the already adsorbed semiconductor light emitting devices 150D are separated, thereby improving the assembly rate.

Meanwhile, as shown in FIGS. 9, 14, 16, and 18, the thickness (t1, t2) of the passivation layer on the upper side of the light emitting layer 150′ may be varied depending on the location. That is, if the upper surface of the light emitting layer 150′ has a first area 150a-1 and a second area 150a-2 surrounding the first area 150a-1, the first passivation layer 157-1 may be placed on the first area 150a-1, and the second passivation layer 157-2 may be placed on the second area 150a-2. In this case, the thickness t1 of the first passivation layer 157-1 is smaller than the thickness t2 of the second passivation layer 157-2, so that the semiconductor light emitting device 150A to 150D is properly assembled during self-assembly, meanwhile, the thickness t1 of the first passivation layer 157-1 is very thin, making it very easy to form contact holes for forming electrode wiring. Accordingly, quick electrical connection can be made and electrical connection failure can be prevented.

Additional scope of applicability of the embodiments will become apparent from the detailed description below: However, since various changes and modifications within the spirit and scope of the embodiments may be clearly understood by those skilled in the art, the detailed description and specific embodiments, such as preferred embodiments, should be understood as being given by way of example only.

### DESCRIPTION OF DRAWINGS

FIG. 1 is a cross-sectional view showing a semiconductor light emitting device according to undisclosed internal technology.

FIG. 2 shows assembly defects due to adsorption of semiconductor light emitting devices.

FIG. 3 shows the living room of a house where a display device according to an embodiment is placed.

FIG. 4 is a block diagram schematically showing a display device according to an embodiment.

FIG. 5 is a circuit diagram showing an example of the pixel of FIG. 4.

FIG. 6 is an enlarged view of the first panel area in the display device of FIG. 3.

FIG. 7 is an enlarged view of area A2 in FIG. 6.

FIG. 8 is a diagram showing an example in which a light emitting device according to an embodiment is assembled on a substrate by a self-assembly method.

FIG. 9 is a cross-sectional view showing a semiconductor light emitting device according to the first embodiment.

FIG. 10 is a bottom view showing a semiconductor light emitting device according to the first embodiment.

FIG. 11 is a plan view showing a display device according to an embodiment.

FIG. 12 is a cross-sectional view showing a display device according to the first embodiment.

FIG. 13 is a cross-sectional view showing a display device according to a second embodiment.

FIG. 14 is a cross-sectional view showing a semiconductor light emitting device according to the second embodiment.

FIG. 15 shows light reflection and current flow in the semiconductor light emitting device according to the second embodiment.

FIG. 16 is a cross-sectional view showing a semiconductor light emitting device according to the third embodiment.

FIG. 17 shows light reflection and current flow in a semiconductor light emitting device according to the third embodiment.

FIG. 18 is a cross-sectional view showing a semiconductor light emitting device according to the fourth embodiment.

FIG. 19 shows the formation of a fluid adsorption layer during self-assembly using a semiconductor light emitting device according to the fourth embodiment.

FIG. 20 is a cross-sectional view showing a display device according to a third embodiment.

FIG. 21 is a cross-sectional view showing a display device according to the fourth embodiment.

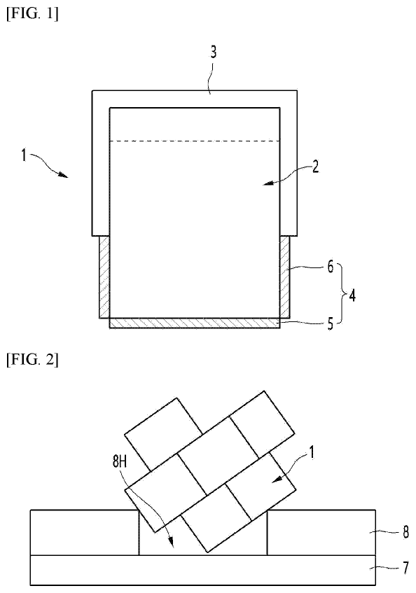

The size, shape, and dimensions of the components shown in the drawings may differ from the actual ones. In addition, even if the same components are shown in different sizes, shapes, and figures between drawings, this is only an example in the drawings, and the same components may have the same size, shape, and numerical value between drawings.

### MODE FOR INVENTION

Hereinafter, embodiments disclosed in the present specification will be described in detail with reference to the attached drawings, but identical or similar components will be assigned the same reference numbers regardless of the reference numerals, and duplicate descriptions thereof will be omitted. The suffixes ‘module’ and ‘part’ for components used in the following description are given or used interchangeably in consideration of ease of specification preparation, and do not have distinct meanings or roles in themselves. Additionally, the attached drawings are intended to facilitate easy understanding of the embodiments disclosed in this specification, and the technical idea disclosed in this specification is not limited by the attached drawings. Additionally, when an element such as a layer, region or substrate is referred to as being ‘on’ another component, this includes either directly on the other element or there may be other intermediate elements in between.

The display device described in this specification may include mobile device such as TV, Shiny G, mobile phone or smart phone, displays for computers such as laptops and desktops, head-up displays (HUDs) for cars, backlight units for displays, displays for VR, AR or MR (mixed reality), light sources, etc. However, the configuration according to the embodiment described in this specification may be equally applied to a device capable of displaying, even if it is a new product type that is developed in the future.

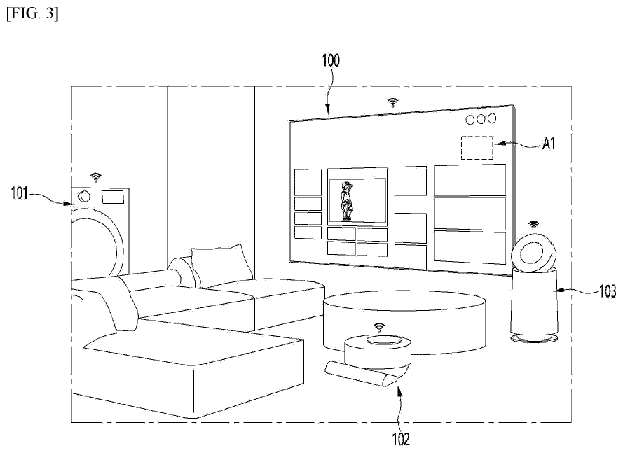

FIG. 3 shows a living room of a house where a display device according to an embodiment is placed.

Referring to FIG. 3, the display device 100 of the embodiment may display the status of various electronic products such as a washing machine 101, a robot vacuum cleaner 102, and an air purifier 103 and it is possible to communicate with each electronic product based on IOT and control each electronic product based on the user's setting data.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the emission of unit pixels arranged in a matrix form. A unit pixel refers to the minimum unit for implementing one color. A unit pixel of a flexible display may be implemented by a light emitting device. In the embodiment, the light emitting device may be Micro-LED or Nano-LED, but is not limited thereto.

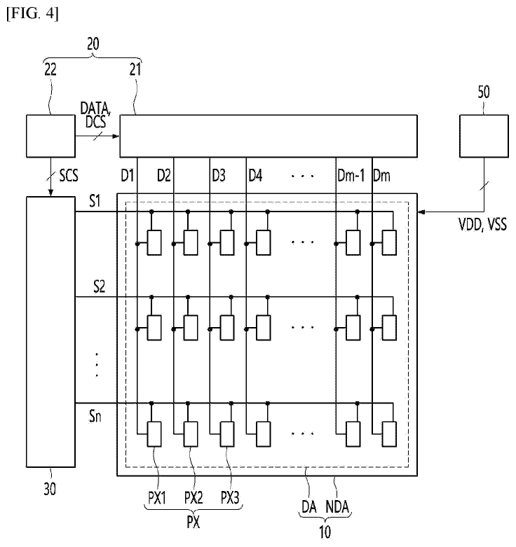

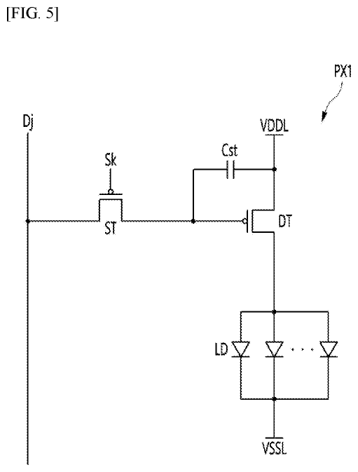

FIG. 4 is a block diagram schematically showing a display device according to an embodiment, and FIG. 5 is a circuit diagram showing an example of the pixel of FIG. 4.

Referring to FIGS. 4 and 5, a display device according to an embodiment may include a display panel 10, a driving circuit 20, a scan driver 30, and a power supply circuit 50.

The display device 100 of the embodiment may drive a light emitting device in an active matrix (AM, Active Matrix) method or a passive matrix (PM, Passive Matrix) method.

The driving circuit 20 may include a data driving unit 21 and a timing control unit 22.

The display panel 10 may be rectangular, but there is no limitation thereto. That is, the display panel 10 may be formed in a circular or oval shape. At least one side of the display panel 10 may be bent to a predetermined curvature.

The display panel may include a display area DA. The display area DA is an area where pixels PX are formed to display an image. The display panel may include a non-display area NDA. The non-display area DNA may be an area excluding the display area DA.

As an example, the display area DA and the non-display area NDA may be defined on the same surface. For example, the non-display area DNA may surround the display area DA on the same side as the display area DA, but this is not limited.

As another example, although not shown in the drawing, the display area DA and the non-display area NDA may be defined on different sides. For example, the display area DA may be defined on the top surface of the substrate, and the non-display area NDA may be defined on the lower surface of the substrate. For example, the non-display area NDA may be defined on the entire or partial area of the lower surface of the substrate.

Meanwhile, in the drawing, it is shown as being divided into a display area DA and a non-display area NDA, but it may not be divided into a display area DA and a non-display area NDA. That is, only the display area DA may exist on the upper surface of the substrate, and the non-display area NDA may not exist. In other words, the entire upper surface of the substrate is the display area DA where images are displayed, and the bezel area that is the non-display area NDA may not exist.

The display panel 10 may include a data lines (D1 to Dm, m is an integer greater than 2), a scan lines (S1 to Sn, n is an integer of 2 or more) that intersect with data lines (D1 to Dm), a high-potential voltage line VDDL supplied with a high-potential voltage VDD, a low-potential voltage line VSSL supplied with a low-potential voltage VSS, and a pixels PX connected to data lines (D1 to Dm) and scan lines (S1 to Sn).

Each of the pixels PX may include a first sub-pixel PX1, a second sub-pixel PX2, and a third sub-pixel PX3. The first sub-pixel PX1 emits a first color light of a first main wavelength, the second sub-pixel PX2 emits a second color light of a second main wavelength and the third sub-pixel PX3 may emit third color light of the third main wavelength. The first color light may be red light, the second color light may be green light, and the third color light may be blue light, but are not limited thereto. Additionally, in FIG. 4, it is illustrated that each of the pixels PX includes three sub-pixels, but the present invention is not limited thereto. That is, each pixel PX may include four or more sub-pixels.

Each of the first sub-pixel PX1, the second sub-pixel PX2, and the third sub-pixel PX3 may be connected to at least one of the data lines (D1 to Dm), at least one of the scan lines (S1 to Sn) and a high potential voltage line VDDL. As shown in FIG. 5, the first sub-pixel PX1 may include light emitting devices LD, a plurality of transistors for supplying current to the light emitting devices LD, and at least one capacitor Cst.

Although not shown in the drawing, each of the first sub-pixel PX1, the second sub-pixel PX2, and the third sub-pixel PX3 may include only one light emitting device LD and at least one capacitor Cst.

Each of the light emitting devices LD may be a semiconductor light emitting diode including a first electrode 154, a plurality of conductivity semiconductor layers, and a second electrode 155. Here, the first electrode 154 may be an anode electrode, and the second electrode 155 may be a cathode electrode, but this is not limited.

The light emitting device LD may be one of a horizontal light emitting device, a flip chip type light emitting device, and a vertical light emitting device.

The plurality of transistors may include a driving transistor DT that supplies current to the light emitting devices LD, and a scan transistor ST that supplies a data voltage to the gate electrode of the driving transistor DT, as shown in FIG. 5. The driving transistor DT may include a gate electrode connected to the source electrode of the scan transistor ST, a source electrode connected to a high-potential voltage line VDDL to which a high-potential voltage VDD is applied, and a drain electrode connected to the first electrodes 154 of light emitting devices LD. The scan transistor ST may include a gate electrode connected to the scan line (Sk, k is an integer satisfying 1≤k≤n), a source electrode connected to the gate electrode of the driving transistor DT and a drain electrode connected to the data line (Dj, j is an integer satisfying 1≤j≤m).

The capacitor Cst is formed between the gate electrode and the source electrode of the driving transistor DT. The storage capacitor Cst charges the difference between the gate voltage and source voltage of the driving transistor DT.

The driving transistor DT and the scan transistor ST may be formed of a thin film transistor. In addition, in FIG. 5, the driving transistor DT and the scan transistor ST are explained with a focus on being formed of a P-type MOSFET (Metal Oxide Semiconductor Field Effect Transistor), but the present invention is not limited thereto. The driving transistor DT and scan transistor ST may be formed of an N-type MOSFET. In this case, the positions of the source and drain electrodes of each of the driving transistor DT and scan transistor ST may be changed.

In addition, in FIG. 5, it is exemplified that each of the first sub-pixel PX1, the second sub-pixel PX2, and the third sub-pixel PX3 includes a 2TIC (2 Transistor-1 capacitor) with one drive transistor DT, one scan transistor ST and one capacitor Cst, but the present invention is not limited to this. Each of the first sub-pixel PX1, the second sub-pixel PX2, and the third sub-pixel PX3 may include a plurality of scan transistors ST and a plurality of capacitors Cst.

Since the second sub-pixel PX2 and the third sub-pixel PX3 may be represented by substantially the same circuit diagram as the first sub-pixel PX1, detailed descriptions thereof will be omitted.

The driving circuit 20 outputs signals and voltages for driving the display panel 10. For this, the driving circuit 20 may include a data driver 21 and a timing control unit 22.

The data driver 21 receives digital video data DATA and source control signal DCS from the timing control unit 22. The data driver 21 converts digital video data DATA into analog data voltages according to the source control signal DCS and supplies them to the data lines (D1 to Dm) of the display panel 10.

The timing control unit 22 receives digital video data DATA and timing signals from the host system. The host system may be an application processor in a smartphone or tablet PC, a monitor, or a system-on-chip in a TV.

The timing control unit 22 generates control signals for controlling the operation timing of the data driver 21 and the scan driver 30. The control signals may include a source control signal DCS for controlling the operation timing of the data driver 21 and a scan control signal SCS for controlling the operation timing of the scan driver 30.

The driving circuit 20 may be disposed in the non-display area NDA provided on one side of the display panel 10. The driving circuit 20 is formed of an integrated circuit IC, and may be mounted on the display panel 10 using a COG (chip on glass) method, a COP (chip on plastic) method, or an ultrasonic bonding method, but the present invention is not limited to this. For example, the driving circuit 20 may be mounted on a circuit board (not shown) rather than on the display panel 10.

The data driver 21 may be mounted on the display panel 10 using a chip on glass (COG) method, a chip on plastic (COP) method, or an ultrasonic bonding method, and the timing control unit 22 may be mounted on a circuit board.

The scan driver 30 receives a scan control signal SCS from the timing control unit 22. The scan driver 30 generates scan signals according to the scan control signal SCS and supplies them to the scan lines S1 to Sn of the display panel 10. The scan driver 30 may include a plurality of transistors and may be formed in the non-display area NDA of the display panel 10. Alternatively, the scan driver 30 may be formed as an integrated circuit, and in this case, it may be mounted on a gate flexible film attached to the other side of the display panel 10.

The power supply circuit 50 may generate voltages necessary for driving the display panel 10 from the main power supplied from the system board and supply them to the display panel 10. For example, the power supply circuit 50 may generate a high potential voltage VDD for driving the light emitting devices LD of the display panel 10 from the main power supply and a low potential voltage VSS and supply them to the high potential voltage line VDDL and the low potential voltage line VSSL of the display panel 10. Additionally, the power supply circuit 50 may generate and supply driving voltages for driving the driving circuit 20 and the scan driver 30 from the main power source.

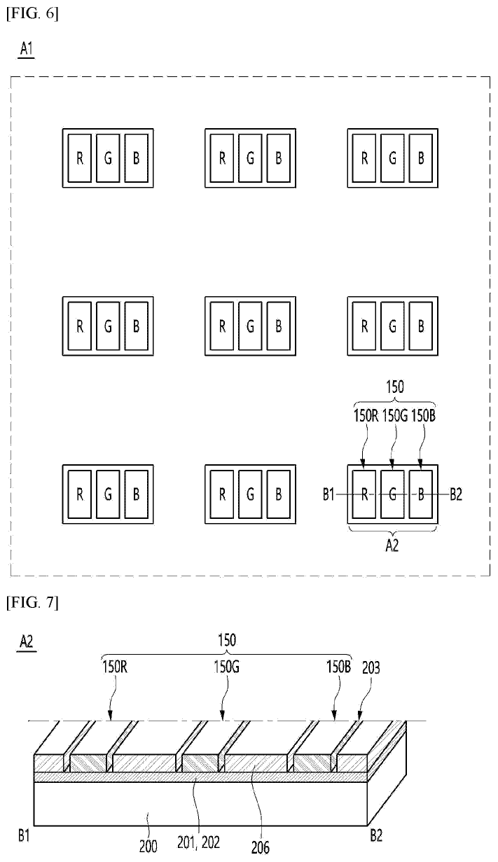

FIG. 6 is an enlarged view of the first panel area in the display device of FIG. 3.

Referring to FIG. 6, the display device 100 of the embodiment may be manufactured by mechanically and electrically connecting a plurality of panel areas, such as the first panel area A1, by tiling.

The first panel area A1 may include a plurality of semiconductor light emitting devices 150 arranged for each unit pixel (PX in FIG. 4).

FIG. 7 is an enlarged view of area A2 in FIG. 6.

Referring to FIG. 7, the display device 100 of the embodiment may include a substrate 200, assembly wiring 201, 202, an insulating layer 206, and a plurality of semiconductor light emitting devices 150. More components may be included.

The assembly wiring may include first assembly wiring 201 and second assembly wiring 202 spaced apart from each other. The first assembly wiring 201 and the second assembly wiring 202 may be provided to generate dielectrophoretic force (DEP force) to assemble the semiconductor light emitting device 150. For example, the semiconductor light emitting device 150 may be one of a horizontal semiconductor light emitting device, a flip chip type semiconductor light emitting device, and a vertical semiconductor light emitting device.

The semiconductor light emitting device 150 may include a red semiconductor light emitting device 150, a green semiconductor light emitting device (150G) and a blue semiconductor light emitting device 150B to form each unit pixel (sub-pixel), but is not limited to this, and a red phosphor and a green phosphor, etc. may be provided to implement red and green colors, respectively.

The substrate 200 may be a support member that supports components placed on the substrate 200 or a protection member that protects the components.

The substrate 200 may be a rigid substrate or a flexible substrate. The substrate 200 may be made of sapphire, glass, silicon, or polyimide. Additionally, the substrate 200 may include a flexible material such as PEN (Polyethylene Naphthalate) or PET (Polyethylene Terephthalate). Additionally, the substrate 200 may be made of a transparent material, but is not limited thereto. The substrate 200 may function as a support substrate in a display panel, and may also function as an assembly substrate when self-assembling a light emitting device.

The substrate 200 may be a backplane equipped with circuits in the sub-pixels PX1, PX2, and PX3 shown in FIGS. 4 and 5, such as transistors (ST, DT), capacitors Cst, signal wirings, etc., but there is no limitation to this.

The insulating layer 206 may include an insulating and flexible organic material such as polyimide, PAC, PEN, PET, polymer, etc., or an inorganic material such as silicon oxide (SiO2) or silicon nitride series (SiNx) and may be integrated with the substrate 200 to form one substrate.

The insulating layer 206 may be a conductive adhesive layer that has adhesiveness and conductivity, and the conductive adhesive layer may be flexible and enable a flexible function of the display device. For example, the insulating layer 206 may be an anisotropic conductive film (ACF) or a conductive adhesive layer such as an anisotropic conductive medium or a solution containing conductive particles. The conductive adhesive layer may be a layer that is electrically conductive in a direction perpendicular to the thickness, but electrically insulating in a direction horizontal to the thickness.

The insulating layer 206 may include an assembly hole 203 into which the semiconductor light emitting device 150 is inserted. Therefore, during self-assembly, the semiconductor light emitting device 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, groove, groove, recess 157H, pocket, etc.

The assembly hole 203 may be different depending on the shape of the semiconductor light emitting device 150. For example, the red semiconductor light emitting device, the green semiconductor light emitting device, and the blue semiconductor light emitting device each have different shapes, and may have an assembly hole 203 having a shape corresponding to the shape of each of these semiconductor light emitting devices. For example, assembly hole 203 may include a first assembly hole 340H for assembling the red semiconductor light emitting device, a second assembly hole 340H for assembling the green semiconductor light emitting device and a third assembly hole 340H for assembling the blue semiconductor light emitting device. For example, the red semiconductor light emitting device has a circular shape, the green semiconductor light emitting device has a first oval shape with a first minor axis and a second major axis, and the blue semiconductor light emitting device may have a second oval shape with a second minor axis and a second major axis, but is not limited thereto. The oval-shaped second major axis of the blue semiconductor light emitting device is larger than the oval-shaped second major axis of the green semiconductor light emitting device, and the second minor axis of the oval shape of the blue semiconductor light emitting device may be smaller than the first minor axis of the oval shape of the green semiconductor light emitting device.

Meanwhile, methods of mounting the semiconductor light emitting device 150 on the substrate 200 may include, for example, a self-assembly method (FIG. 8) and a transfer method.

FIG. 8 is a diagram showing an example in which a light emitting device according to an embodiment is assembled on a substrate by a self-assembly method.

Based on FIG. 8, an example in which a semiconductor light emitting device according to an embodiment is assembled into a display panel by a self-assembly method using an electromagnetic field will be described.

The assembled substrate 200 described later may also function as the panel substrate 200a in a display device after assembly of the light emitting device, but the embodiment is not limited thereto.

Referring to FIG. 8, the semiconductor light emitting device 150 may be inserted into the chamber 1300 filled with fluid 1200, and the semiconductor light emitting device 150 may be moved to the assembly substrate 200 by the magnetic field generated from the assembly device 1100. At this time, the light emitting device 150 adjacent to the assembly hole 207H of the assembly substrate 200 may be assembled to the assembly hole 207H by DEP force caused by the electric field of the assembly wirings. The fluid 1200 may be water such as ultrapure water, but is not limited thereto. The chamber may be called a water tank, container, vessel, etc.

After the semiconductor light emitting device 150 is introduced into the chamber 1300, the assembled substrate 200 may be placed on the chamber 1300. Depending on the embodiment, the assembled substrate 200 may be input into the chamber 1300.

Meanwhile, an electric field is formed in the first assembly wiring 201 and the second assembly wiring 202 as an alternating voltage is applied, and the semiconductor light emitting device 150 inserted into the assembly hole 207H may be fixed by the DEP force caused by this electric field. A gap between the first assembly wiring 201 and the second assembly wiring 202 may be smaller than the width of the semiconductor light emitting device 150 and the width of the assembly hole 207H, and the assembly position of the semiconductor light emitting device 150 using an electric field may be fixed more precisely.

An insulating layer 215 is formed on the first assembly wiring 201 and the second assembly wiring 202, protect the first assembly wiring 201 and the second assembly wiring 202 from the fluid 1200, and may prevent leakage of current flowing through the first assembly wiring 201 and the second assembly wiring 202. For example, the insulating layer 215 may be formed of a single layer or multiple layers of an inorganic insulator such as silica or alumina or an organic insulator. The insulating layer 215 may have a minimum thickness to prevent damage to the first assembly wiring 201 and the second assembly wiring 202 when assembling the semiconductor light emitting device 150, and may have a maximum thickness for the semiconductor light emitting device 150 to be stably assembled.

A partition wall 207 may be formed on the upper part of the insulating layer 215. Some areas of the partition wall 207 may be located on upper part of the first assembly wiring 201 and the second assembly wiring 202, and the remaining area may be located on the upper part of the assembled substrate 200.

Meanwhile, when manufacturing the assembled substrate 200, by removing a portion of the partition wall 340 formed on the upper part of the insulating layer 215, an assembly hole 207H through which each of the semiconductor light emitting devices 150 is coupled and assembled to the assembly substrate 200 may be formed.

An assembly hole 207H where the semiconductor light emitting devices 150 are coupled is formed in the assembly substrate 200, and the surface where the assembly hole 207H is formed may be in contact with the fluid 1200. The assembly hole 207H may guide the exact assembly position of the semiconductor light emitting device 150.

Meanwhile, the assembly hole 207H may have a shape and size corresponding to the shape of the semiconductor light emitting device 150 to be assembled at the corresponding location. Accordingly, it is possible to prevent another semiconductor light emitting device from being assembled or a plurality of semiconductor light emitting devices from being assembled into the assembly hole 207H.

Referring again to FIG. 8, after the assembled substrate 200 is placed in the chamber, the assembly device 1100 that applies a magnetic field may move along the assembled substrate 200. Assembly device 1100 may be a permanent magnet or an electromagnet.

The assembly device 1100 may move while in contact with the assembly substrate 200 in order to maximize the area to which the magnetic field is applied within the fluid 1200. Depending on the embodiment, the assembly device 1100 may include a plurality of magnetic materials or may include a magnetic material of a size corresponding to that of the assembly substrate 200. In this case, the moving distance of the assembly device 1100 may be limited to within a predetermined range.

The semiconductor light emitting device 150 in the chamber 1300 may move toward the assembly device 1100 and the assembly substrate 200 by the magnetic field generated by the assembly device 1100.

The semiconductor light emitting device 150 may enter the assembly hole 207H and be fixed by the DEP force formed by the electric field between the assembly wiring 201 and 202 while moving toward the assembly device 1100.

Specifically, the first and second assembly wirings 201, 202 form an electric field by alternating current power, and DEP force may be formed between the assembly wirings 201, 202 by this electric field. The semiconductor light emitting device 150 may be fixed to the assembly hole 207H on the assembly substrate 200 by this DEP force.

At this time, a predetermined solder layer (not shown) is formed between the light emitting device 150 assembled on the assembly hole 207H of the assembly board 200 and the assembly wiring 201, 202 to improve the bonding strength of the light emitting device 150.

Additionally, after assembly, a molding layer (not shown) may be formed in the assembly hole 207H of the assembled substrate 200. The molding layer may be a transparent resin or a resin containing a reflective material or a scattering material.

By using the above-described self-assembly method using electromagnetic fields, the time required to assemble each semiconductor light emitting device on a substrate may be drastically shortened, making it possible to implement a large-area, high-pixel display more quickly and economically.

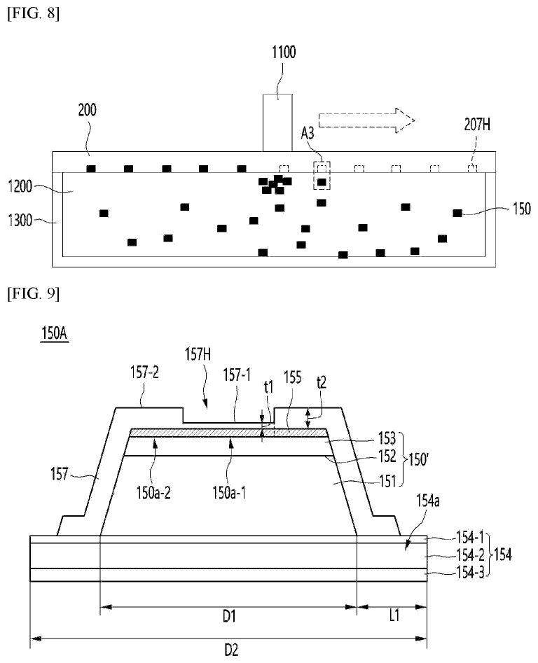

Hereinafter, various embodiments for solving the above-described problem will be described with reference to FIGS. 9 to 21. Descriptions omitted below may be easily understood from FIGS. 3 to 8 and the description given above in relation to the corresponding drawings.

The semiconductor light emitting device described below may have a size of less than a micrometer. For example, the semiconductor light emitting device may have a size of 10 micrometers or less.

Additionally, the semiconductor light emitting device described below may be a vertical semiconductor light emitting device in which current flows vertically.

### First Embodiment

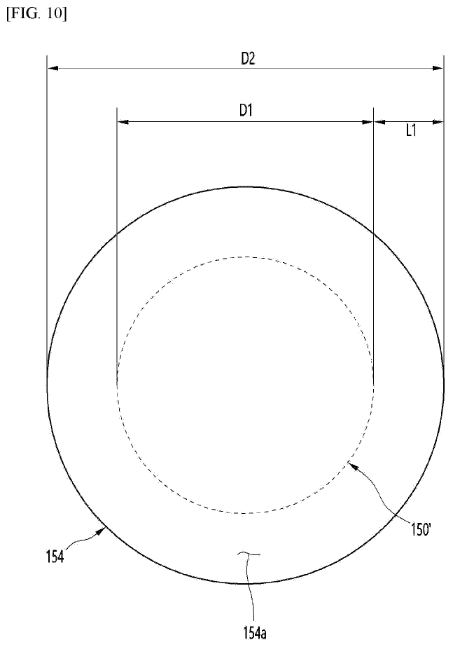

FIG. 9 is a cross-sectional view showing a semiconductor light emitting device according to the first embodiment. FIG. 10 is a bottom view showing a semiconductor light emitting device according to the first embodiment.

Referring to FIGS. 9 and 10, the semiconductor light emitting device 150A according to the first embodiment may include a light emitting layer 150′, a passivation layer 157, a first electrode 154, and a second electrode 155.

The light emitting layer 150′ may emit light of a specific color. Specific color light may be determined by the semiconductor material of the light emitting layer 150′. The specific color light may be, for example, red light, green light, or blue light. Hereinafter, the light emitting layer 150′ will be described as emitting red light, but the light emitting layer 150′ of the embodiment may also emit green light or blue light.

The light emitting layer 150′ may include a plurality of semiconductor layers. For example, the light emitting layer 150′ may include at least one first conductivity semiconductor layer 151, an active layer 152, and at least one second conductivity semiconductor layer 153. The active layer 152 may be disposed on the first conductivity semiconductor layer 151 and the second conductivity semiconductor layer 153 may be disposed on the active layer 152. The first conductivity semiconductor layer 151 may include an n-type dopant, and the second conductivity semiconductor layer 153 may include a p-type dopant, but this is not limited.

The light emitting layer 150′ may have a mesa structure. That is, the side of the light emitting layer 150′ may have an inclined surface. The size (or diameter) of the light emitting layer 150′ may increase from the upper side to the lower side. Although not shown, the light emitting layer 150′ may have a multi-stage structure. Each of the upper areas and lower areas of the light emitting layer 150′ has a different diameter, and each side may have an inclined surface. At this time, the inclination angle of the side of the upper area of the light emitting layer 150′ and the inclination angle of the side of the lower area of the light emitting layer 150′ may be the same, but this is not limited. In this way, due to the multi-stage structure of the light emitting layer 150′, the semiconductor light emitting device 150A may be moved to the correct position without being significantly shaken up and down or turned over during self-assembly, thereby preventing assembly defects.

The passivation layer (157) is made of a material with excellent insulating properties, so it may protect the light emitting layer 150′ and prevent leakage current flowing on the side part of the light emitting layer 150′. In addition, the passivation layer 157 acts as a repulsive force against the DEP force during self-assembly, so that the lower side of the semiconductor light emitting device 150A faces the bottom of the assembly hole 340H to ensure proper assembly.

The passivation layer 157 may surround the light emitting layer 150′. The passivation layer may be disposed along the side part perimeter of the light emitting layer 150′. The passivation layer may be disposed on the upper side of the light emitting layer 150′.

The passivation layer disposed on the upper side of the light emitting layer 150′ may include a first passivation layer 157-1 and a second passivation layer 157-2. The upper surface of the light emitting layer 150′ may have a first area 150a-1 and a second area 150a-2 surrounding the first area 150a-1. In this case, the first passivation layer 157-1 may be placed on the first area 150a-1, and the second passivation layer 157-2 may be placed on the second area 150a-2. Accordingly, the second passivation layer 157-2 may surround the first passivation layer 157-1.

The thickness t1 of the first passivation layer 157-1 and the thickness t2 of the second passivation layer 157-2 may be different. The thickness t1 of the first passivation layer 157-1 may be smaller than the thickness t2 of the second passivation layer 157-2. For example, the thickness t1 of the first passivation layer 157-1 may be less than ½ of the thickness t2 of the second passivation layer 157-2. The lower surface of the first passivation layer 157-1 and the lower surface of the second passivation layer 157-2 may be located on the same horizontal line. Accordingly, the recess 157H may be disposed on the upper side of the passivation layer corresponding to the first area 150a-1 of the light emitting layer 150′.

The passivation layer may be disposed on the upper side of the light emitting layer 150′. At this time, the passivation layer disposed on the upper side of the light emitting layer 150′ is disposed on the second electrode 155, so that the second electrode 155 may not be exposed to the outside. Accordingly, by preventing the second electrode 155 from being affected by DEP force during self-assembly, the semiconductor light emitting device 150A is not turned over so that the second electrode 155 faces downward, thereby preventing assembly defects.

Meanwhile, after the semiconductor light emitting device 150A is assembled on the backplane substrate, electrode wiring may be formed on the upper side of the semiconductor light emitting device 150A. In this case, the semiconductor light emitting device 150A may penetrate the passivation layer and be electrically connected to the second electrode 155 of the semiconductor light emitting device 150A. When the thickness of the passivation layer is thick, it is very difficult to form contact holes for forming electrode wiring. However, as in the embodiment, as the thickness t1 of the first passivation layer 157-1 is smaller than the thickness t2 of the second passivation layer 157-2, during self-assembly, the semiconductor light emitting device 150A is properly assembled, and the thickness t1 of the first passivation layer 157-1 is very thin, making it very easy to form contact holes for forming electrode wiring. Accordingly, quick electrical connection may be made and electrical connection failure may be prevented.

Referring again to FIGS. 9 and 10, the second electrode 155 may be disposed on the light emitting layer 150′. The second electrode 155 may be disposed between the light emitting layer 150′ and the passivation layer.

The second electrode 155 may be in contact with the upper surface of the second conductivity semiconductor layer 153 of the light emitting layer 150′, but this is not limited. Although not shown, the size of the second electrode 155 may be smaller than the size of the light emitting layer 150′. The second electrode 155 is a transparent conductive layer and may include ITO, IZO, etc.

The first electrode 154 may be placed below the light emitting layer 150′.

For example, the first electrode 154 may be a cathode electrode, and the second electrode 155 may be an anode electrode. Therefore, a driving current flows from the second electrode 155 to the first electrode 154 in the light emitting layer 150′, and light of a specific wavelength band may be generated in the light emitting layer 150′ by this driving current.

According to the embodiment, the first electrode 154 may be easily formed to facilitate electrical connection to the first electrode 154 after the semiconductor light emitting device 150A is assembled on the backplane substrate.

According to an embodiment, the assembly rate may be improved by increasing the size D2 of the first electrode 154, thereby increasing the reaction speed of the semiconductor light emitting device 150A to the magnet during self-assembly.

According to an embodiment, by increasing the size D2 of the first electrode 154, the light reflection area of the light emitting layer 150′ may be expanded to improve light efficiency and brightness.

Below; the first electrode 154 will be described in detail.

The size (or area, D2) of the first electrode 154 may be larger than the size (or area, D1) of the light emitting layer 150′. As previously described, the light emitting layer 150′ has a mesa structure, and its size may increase from the upper side to the lower side. In this case, the size D1 of the light emitting layer 150′ may be the size of the lower surface of the light emitting layer 150′. For example, the size D1 of the light emitting layer 150′ may be the size of the lower surface of the first conductivity semiconductor layer 151.

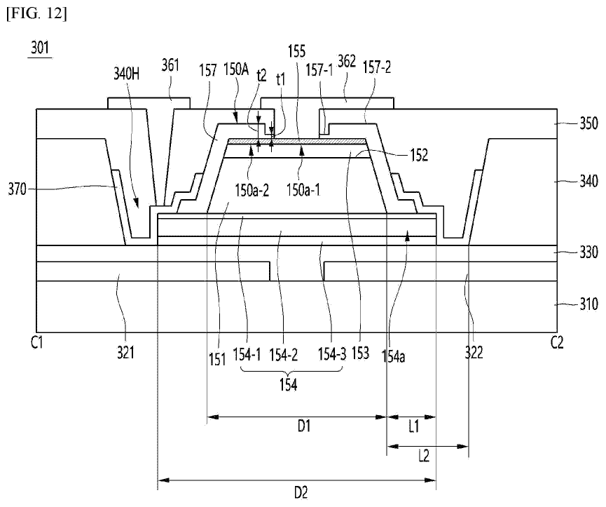

The first electrode 154 may include a protrusion portion 154a protruding outward from the side part of the light emitting layer 150′. The protrusion portion 154a may protrude in an outward direction along the side part perimeter of the light emitting layer 150′. For example, the length (or width, L1) of the protrusion portion 154a may be 1 micrometer or more. As shown in FIG. 12, when the semiconductor light emitting device 150A is assembled on the backplane substrate, the length L1 of the protrusion portion 154a may be smaller than the separation distance L2 between the outer side of the semiconductor light emitting device and the inner side of the assembly hole 340H. Therefore, by maximizing the length L1 of the protrusion portion 154a and maximizing the size D2 of the first electrode 154, as described above, various technical advantages may be obtained by maximizing the size D2 of the first electrode 154.

Meanwhile, the first electrode 154 may have a multilayer structure. That is, the first electrode 154 may include multiple layers. The first electrode 154 may include an ohmic contact layer 154-1, a reflection layer 154-2, and a magnetic layer 154-3, but is not limited thereto. The ohmic contact layer 154-1 may include Au, AuBe, AuGe, etc. The reflection layer 154-2 may include Al, Ag, etc. The magnetic layer 154-3 may include Ni, Co, etc. Although not shown, the first electrode 154 may include an electrode layer (conductive layer) such as Cu, an oxidation prevention layer such as Mo, an adhesive layer such as Cr or Ti, etc. The electrode layer may be disposed between the ohmic contact layer 154-1 and the reflection layer 154-2 or between the reflection layer 154-2 and the magnetic layer 154-3. The adhesive layer may be disposed above and/or below the electrode layer.

The ohmic contact layer 154-1 may be disposed below the light emitting layer 150′. The ohmic contact layer 154-1 may be disposed below the first conductivity semiconductor layer 151 of the light emitting layer 150′. The ohmic contact layer 154-1 may be in contact with the lower surface of the first conductivity semiconductor layer 151. A Schottky barrier is formed at the interface between the first conductivity semiconductor layer 151 containing an n-type dopant and the metal. This is due to the fact that the work function of the metal is greater than that of the first conductivity semiconductor layer 151. Therefore, by using a metal with a small work function as the first electrode 154, an ohmic barrier may be formed for the first conductivity semiconductor layer 151. The entire area of the lower surface of the first conductivity semiconductor layer 151 may be in contact with the ohmic contact layer 154-1. For example, as the ohmic contact layer 154-1 such as Au, AuBe, AuGe, etc. is in contact with the lower surface of the first conductivity semiconductor layer 151, an ohmic barrier may be formed at the interface between the first conductivity semiconductor layer 151 and the ohmic contact layer 154-1. Accordingly, electrical characteristics are improved and low voltage driving is possible, or a higher voltage may be applied to improve light efficiency or brightness.

The ohmic contact layer 154-1 may protrude outward from the side part of the light emitting layer 150′. The ohmic contact layer 154-1 may protrude outward from the side of the passivation layer. As the ohmic contact layer 154-1 protrudes outward, electrical connection by a later process may be facilitated.

The passivation layer may be in contact with the upper surface of the ohmic contact layer 154-1 protruding outward from the side part of the light emitting layer 150′. As the ohmic contact layer 154-1 is in contact with the light emitting layer 150′ and the passivation layer, peeling of the ohmic contact layer 154-1 may be prevented.

The reflection layer 154-2 may be disposed below the ohmic contact layer 154-1. The size of the reflection layer 154-2 may be the same as the size of the ohmic contact layer 154-1, but this is not limited.

The reflection layer 154-2 may improve light efficiency and brightness by reflecting light from the light emitting layer 150′ toward the first electrode 154 forward. To this end, the ohmic contact layer 154-1 may have a thickness thin enough to allow light to pass through.

The reflection layer 154-2 may protrude in an outward direction from the side part of the light emitting layer 150′. The reflection layer 154-2 may protrude outward from the side of the passivation layer. As the reflection layer 154-2 protrudes outward, electrical connection by a later process may be facilitated.

When the light of the light emitting layer 150′ propagates laterally and downward, the light may be reflected forward by the reflection layer 154-2 protruding outward from the side part of the light emitting layer 150′, so light efficiency may be improved.

The magnetic layer 154-3 may be disposed below the reflection layer 154-2. The size of the magnetic layer 154-3 may be the same as the size of the reflection layer 154-2 and/or the ohmic contact layer 154-1, but is not limited thereto.

The magnetic layer 154-3 may improve the assembly rate by increasing the reaction speed of the semiconductor light emitting device 150A to the magnet during self-assembly. In order to increase the reaction speed of the semiconductor light emitting device 150A, the area of the magnetic layer 154-3 may be expanded in the embodiment. For example, the magnetic layer 154-3 may protrude outward from the side part of the light emitting layer 150′. The magnetic layer 154-3 may protrude outward from the side of the passivation layer. As the magnetic layer 154-3 protrudes outward, the overall size of the magnetic layer 154-3 is expanded, so that the reaction speed of the semiconductor light emitting device 150A to the magnet during self-assembly increases, thereby improving the assembly rate.

The outer sides of each of the ohmic contact layer 154-1, the reflection layer 154-2, and the magnetic layer 154-3 may be positioned on the same vertical line.

Hereinafter, a display device equipped with a semiconductor light emitting device 150A according to the first embodiment will be described.

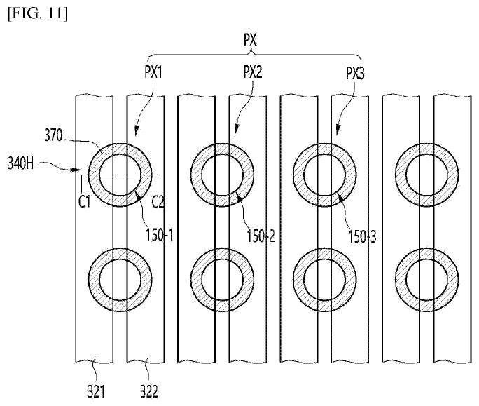

FIG. 11 is a plan view showing a display device according to an embodiment.

Referring to FIG. 11, a display device according to an embodiment includes a plurality of pixels PX, and each of the plurality of pixels PX may include a plurality of sub-pixels PX1, PX2, and PX3.

For example, at least one semiconductor light emitting device 150-1 to 150-3 may be disposed in each of the plurality of sub-pixels PX1, PX2, and PX3. For example, at least one red semiconductor element 150-1 is disposed on the first sub-pixel PX1, at least one green semiconductor light emitting device 150-2 is disposed on the second sub-pixel PX2, and at least one blue semiconductor light emitting device 150-3 may be disposed on the third sub-pixel PX3.

Although the red semiconductor light emitting device 150-1 may be the semiconductor light emitting device 150A according to the first embodiment shown in FIGS. 9 and 10, also the green semiconductor light emitting device 150-2 and/or the blue semiconductor light emitting device 150-3 may have the same shape, structure, and/or function as the semiconductor light emitting device 150A according to the first embodiment except for the semiconductor material of the light emitting layer 150′.

Meanwhile, the plurality of sub-pixels PX1 to PX3 may each include a first assembly wiring 321 and a second assembly wiring 322. During self-assembly, a DEP force is formed by the alternating voltage applied to the first assembly wiring 321 and the second assembly wiring 322, by this DEP force, the semiconductor light emitting devices 151-1 to 151-3 in the fluid may be assembled on the corresponding sub-pixels PX1 to PX3.

To assist in assembling the semiconductor light emitting devices 151-1 to 151-3, each of the plurality of sub-pixels PX1 to PX3 may include an assembly hole 340H. Since a large DEP force is formed within the assembly hole 340H, the semiconductor light emitting device 150-1 to 150-3 moving in the fluid may pass through the assembly hole 340H and be pulled by the large DEP force and be assembled in the assembly hole 340H.

As previously described, the semiconductor light emitting device 150A may be a vertical semiconductor light emitting device in which the first electrode 154 and the second electrode 155 are arranged to face each other in the vertical direction. Each of the plurality of sub-pixels PX1 to PX3 has a small assembly hole 340H, and when a semiconductor light emitting device 150A is placed in this assembly hole 340H, electrical connection of the first electrode 154 on the lower side of the semiconductor light emitting device 150A is not easy. Accordingly, as shown in FIG. 11, by electrically connecting the connection electrode 370 to the first electrode 154 of the semiconductor light emitting device 150A on the side of the semiconductor light emitting device 150A within the assembly hole 340H, electrical connection failure may be prevented. For example, as the connection electrode 370 is arranged along the circumference of the semiconductor light emitting device 150A within the assembly hole 340H, the contact area between the connection electrode 370 and the first electrode 154 is expanded, thereby improving electrical characteristics and enabling low-voltage operation, or applying a higher voltage may improve light efficiency or brightness.

FIG. 12 is a cross-sectional view showing a display device according to the first embodiment.

Referring to FIG. 12, the display device 301 according to the first embodiment may include a backplane substrate, a semiconductor light emitting device 150A, a connection electrode 370, a second insulating layer 350, a first electrode wiring 361 and second electrode wiring 362. The backplane substrate may be called a display substrate.

The backplane substrate includes a substrate 310, a first assembly wiring 321, a second assembly wiring 322, an insulating layer 330 and a partition wall 340, and it may be prepared in advance before self-assembly. Thereafter, the semiconductor light emitting device 150A may be assembled into the assembly hole 340H of the backplane substrate using a self-assembly process. Thereafter, the connection electrode 370, the second insulating layer 350, the first electrode wiring 361, and the second electrode wiring 362 are formed through a post-process, the display device 301 according to the first embodiment may be manufactured.

The substrate 310 is a component of the display device 301 according to the first embodiment, that is, as a support substrate for supporting the semiconductor light emitting device 150A, connection electrode 370, second insulating layer 350, first electrode wiring 361, second electrode wiring 362, etc., and it may be called a lower substrate or backplane substrate. Although not shown, an upper substrate may be disposed on the second electrode wiring 362, but this is not limited.

The first assembly wiring 321 may be disposed on the substrate 310. The second assembly wiring 322 may be disposed on the substrate 310.

For example, the first assembly wiring 321 and the second assembly wiring 322 may each be arranged on the same layer. For example, the first and second assembly wirings 321 and 322 may be in contact with the upper surface of the substrate 310, but this is not limited. For example, the first assembly wiring 321 and the second assembly wiring 322 may each be arranged on the same layer. For example, the first assembly wiring 321 and the second assembly wiring 322 may be arranged parallel to each other. The first assembly wiring 321 and the second assembly wiring 322 may each serve to assemble the semiconductor light emitting device 150A into the assembly hole 340H using a self-assembly method. That is, during self-assembly, an electric field is generated between the first assembly wiring 321 and the second assembly wiring 322 by the voltage supplied to the first assembly wiring 321 and the second assembly wiring 322, the moving semiconductor light emitting device 150A may be assembled in the assembly hole 340H by the assembly device (1100 in FIG. 10) by the DEP force formed by this electric field. The assembly hole 340H may have a larger diameter than the diameter of the semiconductor light emitting device 150A.

The first assembly wiring 321 and the second assembly wiring 322 may each include a plurality of metal layers. Although not shown, the first assembly wiring 321 and the second assembly wiring 322 may each include a main wire and an auxiliary electrode. The main wiring of each of the first assembly wiring 321 and the second assembly wiring 322 may be arranged long along one direction of the substrate 310. The auxiliary electrode of each of the first assembly wiring 321 and the second assembly wiring 322 may extend from the main wiring toward the assembly hole 340H. The auxiliary electrode may be electrically connected to the main wiring. The main wiring may be disposed on the auxiliary wiring, and the lower surface of the main wiring may be in contact with the upper surface of the auxiliary wiring, but this is not limited.

Meanwhile, although not shown, the first assembly wiring 321 and the second assembly wiring 322 may be arranged on different layers.

The first insulating layer 330 may be disposed on the first assembly wiring 321 and the second assembly wiring 322. For example, the first insulating layer 330 may be made of an inorganic material or an organic material. For example, the first insulating layer 330 may be made of a material having a dielectric constant related to DEP force. For example, as the dielectric constant of the first insulating layer 330 increases, the DEP force may increase, but this is not limited. By the assembly hole 340H of the partition wall 340 formed later, the first insulating layer 330 may prevent corrosion by directly contacting the first assembly wiring 321 or the second assembly wiring 322 with fluid during self-assembly.

The partition wall 340 may be disposed on the first insulating layer 330. The first insulating layer 330 may have an assembly hole 340H.

Referring again to FIG. 11, the assembly hole 340H may be formed in each of the plurality of sub-pixels PX1, PX2, and PX3 of each of the plurality of pixels PX. That is, each sub-pixel PX1, PX2, and PX3 may be formed in one assembly hole 340H, but this is not limited. For example, the first insulating layer 330 may be exposed within the assembly hole 340H. For example, the bottom surface 158-2 of the assembly hole 340H may be the top surface of the first insulating layer 330.

The height (or thickness) of the partition wall 340 may be determined by considering the thickness of the semiconductor light emitting device 150A.

The self-assembly process is performed on the backplane substrate configured as above, so that the plurality of semiconductor light emitting devices (150-1 to 150-3 in FIG. 11) may be assembled into a plurality of sub-pixels PX1, PX2, and PX3 of each of the plurality of pixels PX on the substrate 310.

As an example, each of the plurality of red semiconductor light emitting devices 150-1, the plurality of green semiconductor light emitting devices 150-2 and the plurality of blue semiconductor light emitting devices 150-3 may be sequentially assembled into the plurality of sub-pixels PX1, PX2, and PX3 of each of the plurality of pixels PX on the substrate 310.

As another example, the plurality of red semiconductor light emitting devices 150-1, the plurality of green semiconductor light emitting devices 150-2 and the plurality of blue semiconductor light emitting devices 150-3 may be simultaneously assembled in a plurality of sub-pixels PX1, PX2, and PX3 of each of the plurality of pixels PX on the substrate 310. For this purpose, the plurality of red semiconductor light emitting devices 150-1, the plurality of green semiconductor light emitting devices 150-2, and the plurality of blue semiconductor light emitting devices 150-3 may be dropped into the fluid of the chamber and mixed. Subsequently, the same self-assembly process is performed, so that the plurality of red semiconductor light emitting devices 150-1, the plurality of green semiconductor light emitting devices 150-2 and the plurality of blue semiconductor light emitting devices 150-3 may be simultaneously assembled into a plurality of sub-pixels PX1, PX2, and PX3 of each of the plurality of pixels PX on the substrate 310.

For simultaneous self-assembly, the red semiconductor light emitting device 150-1, the green semiconductor light emitting device 150-2, and the blue semiconductor light emitting device 150-3 may each have exclusivity from each other. That is, the red semiconductor light emitting device 150-1, green semiconductor light emitting device 150-2, and blue semiconductor light emitting device 150-3 may each have different shapes or sizes. For example, the red semiconductor light emitting device 150-1 has a circular shape, the green semiconductor light emitting device 150-2 has a first oval shape with a first minor axis and a first major axis, and the blue semiconductor light emitting device 150-3 may have a second oval shape. At this time, the second oval shape may have a second minor axis that is smaller than the first minor axis and a second major axis that is larger than the first major axis.

As previously described, part of the first electrode 154, that is, the ohmic contact layer 154-1 is placed below the light emitting layer 150′, the reflection layer 154-2 is placed below the light emitting layer 150′, and the magnetic layer 154-3 may be disposed below the reflection layer 154-2. At this time, the ohmic contact layer 154-1, the reflection layer 154-2, and/or the magnetic layer 154-3 may protrude outward from the side part of the light emitting layer 150′.

Referring again to FIG. 12, after the semiconductor light emitting device 150A is assembled, an electrical connection may be formed using a post-process. That is, the connection electrode 370, the second insulating layer 350, the first electrode wiring 361, and the second electrode wiring 362 may be formed using a post-process.

The connection electrode 370 may be placed in the assembly hole 340H. The connection electrode 370 may electrically connect the semiconductor light emitting device 150A and the first electrode wiring 361. As will be explained later, the first electrode wiring 361 may be electrically connected to the upper side of the connection electrode 370 through the second insulating layer 350.

The connection electrode 370 may be formed using a sputtering method. As an example, a metal film may be formed and patterned on the substrate 310 using a sputtering process, so that the connection electrode 370 may be formed along the perimeter of the semiconductor light emitting device 150A in the assembly hole 340H.

The connection electrode 370 may be electrically connected to the protrusion portion 154a of the first electrode 154 that protrudes outward from the side part of the light emitting layer 150′. For example, the connection electrode 370 may be connected to the side of the magnetic layer 154-3 of the first electrode 154. For example, the connection electrode 370 may be connected to the side of the reflection layer 154-2 of the first electrode 154. For example, the connection electrode 370 may be connected to the side of the ohmic contact layer 154-1 of the first electrode 154. For example, the connection electrode 370 may be connected to the upper surface of the ohmic contact layer 154-1 of the first electrode 154. In this way, by connecting the connection electrode 370 to the side or upper side of the protrusion portion 154a protruding outward from the side part of the light emitting layer 150′, the electrical characteristics may be improved by increasing the contact area between the lead electrode and the first electrode 154. Accordingly, light efficiency and luminance may be improved.

Although not shown, another insulating layer (hereinafter referred to as a fixed insulating layer) may be disposed between the semiconductor light emitting device 150A and the first insulating layer 330. The fixed insulating layer may fix the semiconductor light emitting device 150A to the first insulating layer 330. The fixed insulating layer may be made of an organic material or a photosensitive material, but is not limited thereto.

The fixed insulating layer may have a shape corresponding to the shape of the semiconductor light emitting device 150A. For example, the diameter (or width) of the fixed insulating layer may be the same as the diameter (or width) of the semiconductor light emitting device 150A, but this is not limited. For example, the fixed insulating layer may have a shape corresponding to the shape of the first conductivity semiconductor layer 151 and/or the shape of the electrode 154 of the semiconductor light emitting device 150A. For example, the thickness of the fixed insulating layer may be smaller than the thickness of the first insulating layer 330. For example, the thickness of the fixed insulating layer may be smaller than the thickness of the electrode 154 of the semiconductor light emitting device 150A.

The second insulating layer 350 may be disposed on the partition wall 340. The second insulating layer 350 may be disposed on the semiconductor light emitting device 150A. The second insulating layer 350 may be disposed on the connection electrode 370 disposed in the assembly hole 340H. The second insulating layer 350 may be a planarization layer to easily form the second electrode wiring 362 or other layers. Accordingly, the top surface of the second insulating layer 350 may have a straight plane. The first insulating layer 330 and the second insulating layer 350 may be made of an organic material or an inorganic material. For example, at least one of the first insulating layer 330 and the second insulating layer 350 may be made of an organic material.

The first electrode wiring 361 and the second electrode wiring 362 may be disposed on the same layer, for example, the second insulating layer 350. The first electrode wiring 361 may be disposed on the second insulating layer 350. The first electrode wiring 361 may be electrically connected to the upper side of the connection electrode 370 through the second insulating layer 350. The second electrode wiring 362 may be disposed on the second insulating layer 350. The second electrode wiring 362 may be electrically connected to the second electrode 155 of the semiconductor light emitting device 150A through the second insulating layer 350 and the passivation layer.

As shown in FIG. 9, in the passivation layer, The thickness t1 of the first passivation layer 157-1 on the first area 150a-1 of the upper surface of the light emitting layer 150′ is smaller than the thickness t2 of the second passivation layer 157-2 on the second area 150a-2. Therefore, a contact hole penetrating the first passivation layer 157-1 must be formed to place the second electrode wiring 362. Since the thickness t1 of the first passivation layer 157-1 is smaller than the thickness t2 of the second passivation layer 157-2, it is easy to form a contact hole in the first passivation layer 157-1.

Accordingly, a (+) voltage is applied to the second electrode wiring 362 and a (−) voltage is applied to the first electrode wiring 361, in the light emitting layer 150′, a driving current flows from the second electrode 155 to the first electrode 154, therefore light in a specific wavelength band determined by the semiconductor material of the light emitting layer 150′ may be generated.

In this case, light from the light emitting layer 150′ toward the first electrode 154 may be reflected by the reflection layer 154-2. In addition, light that travels laterally in the light emitting layer 150′ and is refracted and heads downward may be reflected forward by the reflection layer 154-2 protruding outward from the side part of the light emitting layer 150′. Accordingly, light efficiency and luminance may be improved.

The portion of the ohmic contact layer 154-1 protrudes outward from the side part of the light emitting layer 150′, thereby connecting the connection electrode 370 to the protruding ohmic contact layer 154-1, electrical characteristics may be improved.

As the portion of the magnetic layer 154-3 protrudes outward from the side part of the light emitting layer 150′, during self-assembly, the reaction speed of the semiconductor light emitting device 150A to the magnet increases, thereby improving the assembly rate.

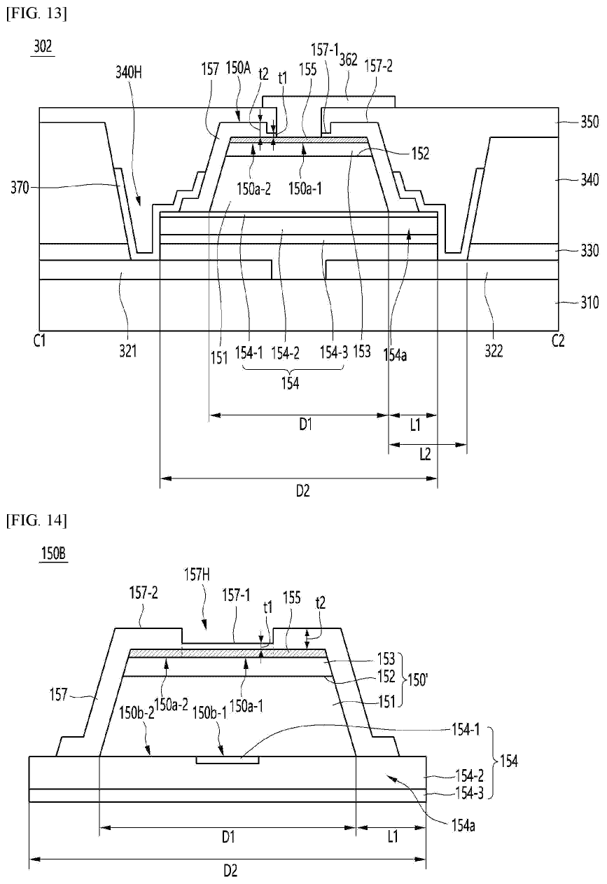

FIG. 13 is a cross-sectional view showing a display device according to a second embodiment.

The second embodiment is the same as the first embodiment (FIG. 12) except that the connection electrode 370 is connected to the first assembly wiring 321 and/or the second assembly wiring 322. In the second embodiment, components having the same shape, structure, and/or function as those of the first embodiment are assigned the same reference numerals and detailed descriptions are omitted.

Referring to FIG. 13, the display device 302 according to the second embodiment may include a backplane substrate, a semiconductor light emitting device 150A, a connection electrode 370, a second insulating layer 350, and electrode wiring 362.

The connection electrode 370 may be electrically connected to the first assembly wiring 321 and/or the second assembly wiring 322 through the first insulating layer 330. After the semiconductor light emitting device 150A is assembled on the backplane substrate using a self-assembly process, the first insulating layer 330 is removed along the circumference of the semiconductor light emitting device 150A within the assembly hole 340H using an etching process, thereby the first assembly wiring 321 and/or the second assembly wiring 322 may be exposed to the outside. Thereafter, the connection electrode 370 is formed within the assembly hole 340H, the first electrode 154 of the semiconductor light emitting device 150A may be connected to the first assembly wiring 321 and/or the second assembly wiring 322 by the connection electrode 370.

Since the connection electrode 370 is connected to the first assembly wiring 321 and/or the second assembly wiring 322, as in the first embodiment (FIG. 12), the first electrode wiring 361 may be omitted. According to the first embodiment (FIG. 12), since the first electrode wiring 361 and the second electrode wiring 362 must be formed to be spaced apart from each other in the very small size of the first sub-pixel PX1, it is difficult to secure the desired area of each of the first electrode wiring 361 and the second electrode wiring 362 on the first sub-pixel PX1. Additionally, if a sufficient separation distance is not secured between the first electrode wiring 361 and the second electrode wiring 362, an electrical short may occur between the first electrode wiring 361 and the second electrode wiring 362. However, according to the second embodiment, the first assembly wiring 321 of the first embodiment (FIG. 12) may be omitted, so the problem occurring in the first embodiment (FIG. 12) may be solved.

### Second Embodiment

FIG. 14 is a cross-sectional view showing a semiconductor light emitting device according to the second embodiment.

The second embodiment is the same as the first embodiment (FIG. 9) except for the ohmic contact layer 154-1 of the first electrode 154. In the second embodiment, components having the same shape, structure, and/or function as those of the first embodiment are assigned the same reference numerals and detailed descriptions are omitted.

Referring to FIG. 14, the semiconductor light emitting device 150B according to the second embodiment may include a light emitting layer 150′, a passivation layer 157, a first electrode 154, and a second electrode 155.

The first electrode 154 may be placed below the light emitting layer 150′.

For example, the first electrode 154 may be a cathode electrode, and the second electrode 155 may be an anode electrode. Therefore, a driving current flows from the second electrode 155 to the first electrode 154 in the light emitting layer 150′, and light of a specific wavelength band may be generated in the light emitting layer 150′ by this driving current.

The size (or area, D2) of the first electrode 154 may be larger than the size (or area, D1) of the light emitting layer 150′. For example, the size D1 of the light emitting layer 150′ may be the size of the lower surface of the first conductivity semiconductor layer 151 of the light emitting layer 150′.

The first electrode 154 may include a protrusion portion 154a protruding outward from the side part of the light emitting layer 150′. The protrusion portion 154a may protrude in an outward direction along the side part perimeter of the light emitting layer 150′. For example, the length (or width, L1) of the protrusion portion 154a may be 1 micrometer or more. When a semiconductor light emitting device 150B is assembled on the backplane substrate, the length L1 of the protrusion portion 154a may be smaller than the separation distance L2 between the outer side of the semiconductor light emitting device and the inner side of the assembly hole 340H. Therefore, by maximizing the length L1 of the protrusion portion 154a and maximizing the size D2 of the first electrode 154, as described above, various technical advantages may be obtained by maximizing the size D2 of the first electrode 154.

Meanwhile, the first electrode 154 may have a multilayer structure. That is, the first electrode 154 may include multiple layers. The first electrode 154 may include an ohmic contact layer 154-1, a reflection layer 154-2, and a magnetic layer 154-3, but is not limited thereto. Although not shown, the first electrode 154 may include an electrode layer (conductive layer) such as Cu, an oxidation prevention layer, an adhesive layer, etc.

The ohmic contact layer 154-1 and the reflection layer 154-2 may be disposed on the same surface, for example, the lower surface of the light emitting layer 150′. The ohmic contact layer 154-1 and the reflection layer 154-2 may be disposed on the lower surface of the first conductivity semiconductor layer 151 of the light emitting layer 150′.

The lower surface of the light emitting layer 150′ may include a first area 150b-1 and a second area 150b-2 surrounding the first area 150b-1. In this case, the ohmic contact layer 154-1 may be placed under the first area 150b-1, and the reflection layer 154-2 may be placed under the second area 150b-2. The ohmic contact layer 154-1 may be in contact with the lower surface of the first area 150b-1, and the reflection layer 154-2 may be in contact with the lower surface of the second area 150b-2. The reflection layer 154-2 may surround the ohmic contact layer 154-1.

The reflection layer 154-2 may be disposed below the ohmic contact layer 154-1. That is, the reflection layer 154-2 may be in contact with the lower surface of the ohmic contact layer 154-1 corresponding to the first area 150b-1.

The thickness of the reflection layer 154-2 may be greater than the thickness of the ohmic contact layer 154-1. The lower surface of the reflection layer 154-2 may have a straight plane. That is, the lower surface of the reflection layer 154-2 under the first area 150b-1 and the lower surface of the reflection layer 154-2 under the second area 150b-2 may be located on the same horizontal line.

In this way, by arranging the ohmic contact layer 154-1 and the reflection layer 154-2 on the same surface, a current concentration effect may be obtained and light reflectance may be increased.

Since the plurality of semiconductor layers constituting the light emitting layer 150′ and the thickness of each of these plural semiconductor layers are fixed, it is difficult to reduce the thickness of the semiconductor light emitting device 150B. Accordingly, when the semiconductor light emitting device 150B becomes smaller, the diameter (or width) of the semiconductor light emitting device 150B may become smaller. Meanwhile, the side surface of the light emitting layer 150′ may be formed using mesa etching. While such mesa etching is performed, the side surface of the light emitting layer 150′ may be damaged, forming a non-emissive area in which light is not generated on the side surface of the light emitting layer 150′. Accordingly, as the size of the semiconductor light emitting device 150B becomes smaller, the size of the non-emission area where light is not generated becomes relatively larger compared to the overall size of the light emitting layer 150′, and the decrease in luminance may become more severe.

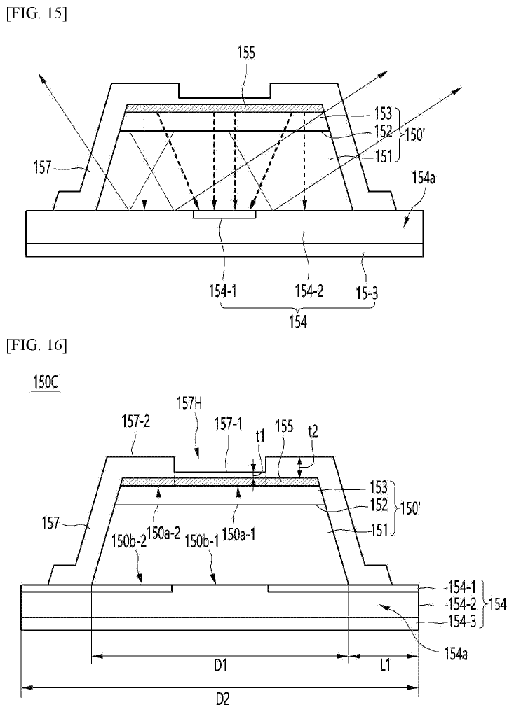

According to the embodiment, as shown in FIG. 15, by placing the ohmic contact layer 154-1 under the central area of the light emitting layer 150′, that is, below the first area 150b-1 of the lower surface of the light emitting layer 150′, and by allowing the driving current (dotted arrow) flowing within the light emitting layer 150′ to be concentrated toward the ohmic contact layer 154-1 rather than the reflection layer 154-2, more light is generated and luminance is improved.

According to the embodiment, by placing the reflection layer 154-2 under the second area 150b-2 on the lower surface of the light emitting layer 150′, light (solid arrow) from the light emitting layer 150′ toward the first electrode 154 is reflected forward by the reflection layer 154-2, thereby improving light efficiency and brightness.

Meanwhile, a magnetic layer 154-3 may be disposed under the light emitting layer 150′. The magnetic layer 154-3 may be disposed below the ohmic contact layer 154-1. The magnetic layer 154-3 may be disposed below the reflection layer 154-2. The magnetic layer 154-3 may be in contact with the lower surface of the reflection layer 154-2. The size of the reflection layer 154-2 and the size of the magnetic layer 154-3 may be the same, but this is not limited.

### Third Embodiment

FIG. 16 is a cross-sectional view showing a semiconductor light emitting device according to a third embodiment.

The third embodiment is the same as the first embodiment (FIG. 9) or the second embodiment (FIG. 14) except for the ohmic contact layer 154-1 and reflection layer 154-2 of the first electrode 154. In the third embodiment, components having the same shape, structure, and/or function as those of the first or second embodiment are assigned the same reference numerals and detailed descriptions are omitted.

Referring to FIG. 16, the semiconductor light emitting device 150C according to the third embodiment may include a light emitting layer 150′, a passivation layer 157, a first electrode 154, and a second electrode 155.

The first electrode 154 may be placed below the light emitting layer 150′.

For example, the first electrode 154 may be a cathode electrode, and the second electrode 155 may be an anode electrode. Therefore, a driving current flows from the second electrode 155 to the first electrode 154 in the light emitting layer 150′, and light of a specific wavelength band may be generated in the light emitting layer 150′ by this driving current.

The size (or area, D2) of the first electrode 154 may be larger than the size (or area, D1) of the light emitting layer 150′. For example, the size D1 of the light emitting layer 150′ may be the size of the lower surface of the first conductivity semiconductor layer 151 of the light emitting layer 150′.

The first electrode 154 may include a protrusion portion 154a protruding outward from the side part of the light emitting layer 150′. The protrusion portion 154a may protrude in an outward direction along the side part perimeter of the light emitting layer 150′. For example, the length (or width, L1) of the protrusion portion 154a may be 1 micrometer or more. As shown in FIG. 12, when the semiconductor light emitting device 150C is assembled on the backplane substrate, the length L1 of the protrusion portion 154a may be smaller than the separation distance L2 between the outer side of the semiconductor light emitting device and the inner side of the assembly hole 340H. Therefore, by maximizing the length L1 of the protrusion portion 154a and maximizing the size D2 of the first electrode 154, as described above, various technical advantages may be obtained by maximizing the size D2 of the first electrode 154.

Meanwhile, the first electrode 154 may have a multilayer structure. That is, the first electrode 154 may include multiple layers. The first electrode 154 may include an ohmic contact layer 154-1, a reflection layer 154-2, and a magnetic layer 154-3, but is not limited thereto. Although not shown, the first electrode 154 may include an electrode layer (conductive layer) such as Cu, an oxidation prevention layer, an adhesive layer, etc.

The ohmic contact layer 154-1 and the reflection layer 154-2 may be disposed on the same surface, for example, the lower surface of the light emitting layer 150′. The ohmic contact layer 154-1 and the reflection layer 154-2 may be disposed on the lower surface of the first conductivity semiconductor layer 151 of the light emitting layer 150′.

The lower surface of the light emitting layer 150′ may include a first area 150b-1 and a second area 150b-2 surrounding the first area 150b-1. In this case, the ohmic contact layer 154-1 may be placed under the second area 150b-2, and the reflection layer 154-2 may be placed under the first area 150b-1. The ohmic contact layer 154-1 may be in contact with the lower surface of the second area 150b-2, and the reflection layer 154-2 may be in contact with the lower surface of the first area 150b-1. The reflection layer 154-2 may surround the ohmic contact layer 154-1.

The ohmic contact layer 154-1 is disposed below the second area 150b-2 and may protrude outward from the side part of the light emitting layer 150′.

The reflection layer 154-2 may be disposed below the ohmic contact layer 154-1. The reflection layer 154-2 may be disposed below the ohmic contact layer 154-1 corresponding to the second area 150b-2. That is, the reflection layer 154-2 may be in contact with the lower surface of the ohmic contact layer 154-1 corresponding to the first area 150b-1. The reflection layer 154-2 may be disposed below the lower surface of the light emitting layer 150′ and may protrude in an outward direction from the side part of the light emitting layer 150′.

The thickness of the reflection layer 154-2 may be greater than the thickness of the ohmic contact layer 154-1. The lower surface of the reflection layer 154-2 may have a straight plane. That is, the lower surface of the reflection layer 154-2 under the first area 150b-1 and the lower surface of the reflection layer 154-2 under the second area 150b-2 may be located on the same horizontal line.

In this way, by arranging the ohmic contact layer 154-1 and the reflection layer 154-2 on the same surface, a current concentration effect may be obtained and light reflectance may be increased.

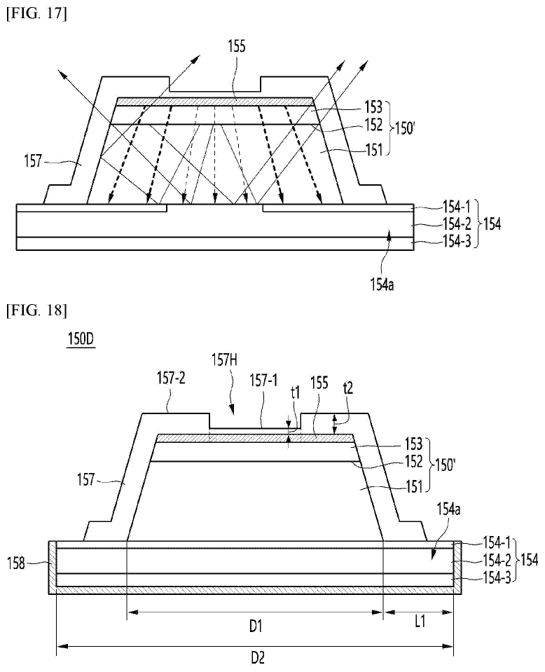

According to the embodiment, as shown in FIG. 17, by placing the ohmic contact layer 154-1 under the edge area of the light emitting layer 150′, that is, below the second area 150b-2 of the lower surface of the light emitting layer 150′, by allowing the driving current (dotted arrow) flowing within the light emitting layer 150′ to be concentrated toward the ohmic contact layer 154-1 rather than the reflection layer 154-2, more light may be generated and luminance may be improved.

According to the embodiment, the ohmic contact layer 154-1 may protrude in an outward direction from the side part of the light emitting layer 150′. The protruding ohmic layer may self-assemble to increase the contact area with the connection electrode 370 formed after the semiconductor light emitting device 150C is assembled on the backplane substrate. Accordingly, electrical characteristics are improved and low voltage driving is possible, or a higher voltage may be applied to improve light efficiency or brightness.

According to the embodiment, as the reflection layer 154-2 is disposed below the first area 150b-1 on the lower surface of the light emitting layer 150′, light (solid arrow) from the light emitting layer 150′ toward the first electrode 154 is reflected forward by the reflection layer 154-2, thereby improving light efficiency and brightness.

Meanwhile, a magnetic layer 154-3 may be disposed under the light emitting layer 150′. The magnetic layer 154-3 may be disposed below the reflection layer 154-2. The size of the reflection layer 154-2 and the size of the magnetic layer 154-3 may be the same, but this is not limited.

### Fourth Embodiment

FIG. 18 is a cross-sectional view showing a semiconductor light emitting device according to the fourth embodiment.

The fourth embodiment is the same as the first embodiment except for the metal oxide layer. In the fourth embodiment, the same components as those in the first embodiment are given the same reference numerals and detailed descriptions are omitted. The fourth embodiment may be equally applied to the second or third embodiments.

Referring to FIG. 18, the semiconductor light emitting device 150D according to the fourth embodiment may include a light emitting layer 150′, a passivation layer 157, a first electrode 154, and a second electrode 155.

The first electrode 154 may be placed below the light emitting layer 150′.

For example, the first electrode 154 may be a cathode electrode, and the second electrode 155 may be an anode electrode. Therefore, a driving current flows from the second electrode 155 to the first electrode 154 in the light emitting layer 150′, and light of a specific wavelength band may be generated in the light emitting layer 150′ by this driving current.

The size (or area, D2) of the first electrode 154 may be larger than the size (or area, D1) of the light emitting layer 150′. For example, the size D1 of the light emitting layer 150′ may be the size of the lower surface of the first conductivity semiconductor layer 151 of the light emitting layer 150′.

The first electrode 154 may include a protrusion portion 154a protruding outward from the side part of the light emitting layer 150′. The protrusion portion 154a may protrude in an outward direction along the side part perimeter of the light emitting layer 150′. For example, the length (or width, L1) of the protrusion portion 154a may be 1 micrometer or more. When a semiconductor light emitting device 150D is assembled on the backplane substrate, the length L1 of the protrusion portion 154a may be smaller than the separation distance L2 between the outer side of the semiconductor light emitting device and the inner side of the assembly hole 340H. Therefore, by maximizing the length L1 of the protrusion portion 154a and maximizing the size D2 of the first electrode 154, as described above, various technical advantages may be obtained by maximizing the size D2 of the first electrode 154.

Meanwhile, the first electrode 154 may have a multilayer structure. That is, the first electrode 154 may include multiple layers. The first electrode 154 may include an ohmic contact layer 154-1, a reflection layer 154-2, and a magnetic layer 154-3, but is not limited thereto. Although not shown, the first electrode 154 may include an electrode layer (conductive layer) such as Cu, an oxidation prevention layer, an adhesive layer, etc.

The ohmic contact layer 154-1 is disposed below the light emitting layer 150′, the reflection layer 154-2 is disposed below the ohmic contact layer 154-1, and the magnetic layer 154-3 may be disposed below the reflection layer 154-2.

Meanwhile, a metal oxide layer may surround the first electrode 154. The metal oxide layer may prevent assembly defects by preventing adsorption between semiconductor light emitting devices 150D during self-assembly. Metal oxides may include, for example, TiO2, ZnO, WO3, etc.

The metal oxide layer may be placed under the magnetic layer 154-3. A metal oxide layer may be disposed on the side of the magnetic layer 154-3. A metal oxide layer may be disposed on the side of the reflection layer 154-2. A metal oxide layer may be disposed on the side of the ohmic contact layer 154-1.

Although not shown, a metal oxide layer may be placed on the side of the passivation layer. Although not shown, the metal oxide layer may be disposed on the edge area of the top surface of the ohmic contact layer 154-1.

When the first electrode 154 is exposed to the outside, the semiconductor light emitting devices 150D may stick to each other and form a lump during self-assembly. These lumps are much larger than the inner diameter of the assembly hole 340H on the backplane substrate, causing assembly defects.

However, as in the embodiment, the metal oxide surrounds the first electrode 154 and the first electrode 154 is not exposed to the outside, so the semiconductor light emitting devices 150D may not stick to each other during self-assembly. Accordingly, the semiconductor light emitting devices 150D are each assembled in the corresponding assembly hole 340H of the backplane substrate, thereby preventing assembly defects and improving the assembly rate.

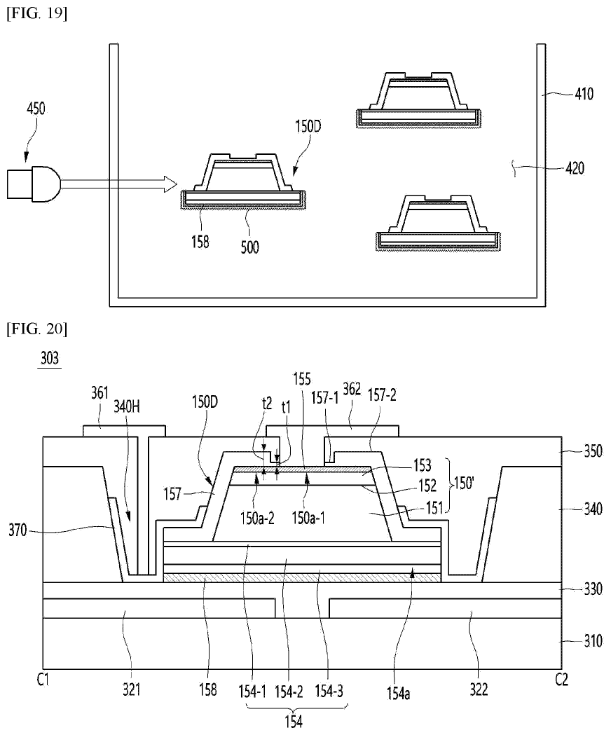

In particular, as shown in FIG. 19, when light is irradiated from the lighting device 450 to the metal oxide provided in the semiconductor light emitting device 150D dropped into the fluid 420 of the chamber 410 during self-assembly, a superhydrophilic phenomenon may occur on the surface of the metal oxide, thereby forming the fluid adsorption layer 500. This fluid adsorption layer 500 may prevent the semiconductor light emitting devices 150D from adhering to each other by interfering with adsorption between the semiconductor light emitting devices 150D. In addition, even if a lump is formed by the semiconductor light emitting devices 150D sticking together, when light from the lighting device 450 is irradiated to the lump, a fluid adsorption layer 500 is formed on the surface of the metal oxide of each semiconductor light emitting device 150D constituting the lump, and by this fluid adsorption layer 500, the adsorption of the semiconductor light emitting device 150D is released and the semiconductor light emitting devices 150D may be separated from each other. Thereafter, the fluid adsorption layer 500 may be removed through a drying process, but this is not limited.

Therefore, the metal oxide layer surrounds the second electrode 155 and light is irradiated to the metal oxide during self-assembly, so that the semiconductor light emitting devices 150D do not stick to each other, thereby preventing assembly defects and improving the assembly rate.

FIG. 20 is a cross-sectional view showing a display device according to a third embodiment.

The third embodiment is the same as the first embodiment (FIG. 12) except for the semiconductor light emitting device 150D. In the third embodiment, components having the same shape, structure, and/or function as those of the first embodiment (FIG. 12) are assigned the same reference numerals and detailed descriptions are omitted.

Referring to FIG. 20, The display device 303 according to the third embodiment may include a backplane substrate, a semiconductor light emitting device 150D, a connection electrode 370, a second insulating layer 350, a first electrode wiring 361 and a second electrode wiring 362.

The semiconductor light emitting device 150D may be a semiconductor light emitting device 150D according to the fourth embodiment.

Unlike the semiconductor light emitting device 150D according to the fourth embodiment, in an embodiment, the metal oxide layer may be removed on the side of the first electrode 154 of the semiconductor light emitting device 150D disposed on the backplane substrate and exposed to the outside. The connection electrode 370 may be connected to the exposed side of the first electrode 154.

The metal oxide layer has lower electrical conductivity than the ohmic contact layer 154-1 constituting the first electrode 154, and thus has poor electrical properties. That is, when the connection electrode 370 is connected to the ohmic contact layer 154-1 through metal oxide, electrical characteristics may be deteriorated.

However, as in the embodiment, after the metal oxide on the side of the first electrode 154 is removed, the connection electrode 370 is connected directly to the side of the first electrode 154, so that the electrical characteristics may be improved.

After the semiconductor light emitting device 150D is assembled on the backplane substrate using a self-assembly process, the metal oxide layer on the side of the first electrode 154 of the semiconductor light emitting device 150D may be removed. Afterwards, a photolithography process is performed so that the connection electrode 370 may be directly connected to the side of the first electrode 154.

Meanwhile, the first electrode wiring 361 and the second electrode wiring 362 may each be electrically connected to the semiconductor light emitting device 150D through the second insulating layer 350. The first electrode wiring 361 is connected to the upper side of the connection electrode 370 through the second insulating layer 350, and the second electrode wiring 362 may be connected to the second electrode 155 of the semiconductor light emitting device 150D through the second insulating layer 350 and the passivation layer.

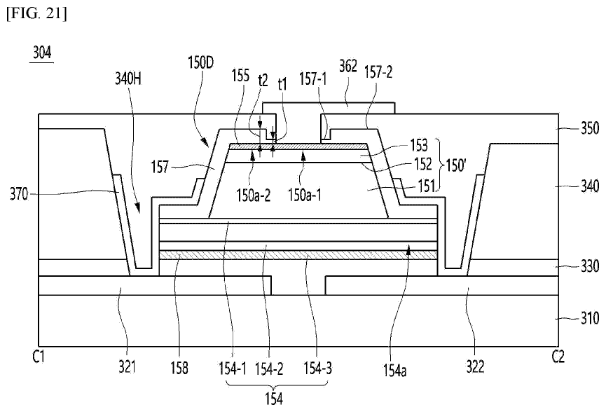

FIG. 21 is a cross-sectional view showing a display device according to the fourth embodiment.

The fourth embodiment is the same as the second embodiment (FIG. 13) except for the semiconductor light emitting device 150D. In the fourth embodiment, components having the same shape, structure, and/or function as those of the second embodiment (FIG. 13) are assigned the same reference numerals and detailed descriptions are omitted.

Referring to FIG. 21, the display device 304 according to the fourth embodiment may include a backplane substrate, a semiconductor light emitting device 150D, a connection electrode 370, a second insulating layer 350, and an electrode wiring 362.

The semiconductor light emitting device 150D may be a semiconductor light emitting device 150D according to the fourth embodiment.

Unlike the semiconductor light emitting device 150D according to the fourth embodiment, in an embodiment, the metal oxide layer may be removed on the side of the first electrode 154 of the semiconductor light emitting device 150D disposed on the backplane substrate and exposed to the outside. The connection electrode 370 may be connected to the exposed side of the first electrode 154.

According to an embodiment, the connection electrode 370 is directly connected to the side of the first electrode 154 instead of the metal oxide on the side of the first electrode 154, thereby improving electrical characteristics.

Meanwhile, as the first assembly wiring 321 and/or the second assembly wiring 322 are connected to the lower side of the connection electrode 370, unlike the third embodiment (FIG. 20), by omitting the first electrode wiring 361, electrical short circuit between the first electrode wiring 361 and the second electrode wiring 362 may be prevented. Additionally, by disposing only the electrode wiring 362 in the first sub-pixel PX1, the area of the electrode wiring 362 may be increased, thereby improving electrical characteristics.

Meanwhile, the display device described above may be a display panel. That is, in the embodiment, the display device and the display panel may be understood to have the same meaning. In an embodiment, a display device in a practical sense may include a display panel and a controller (or processor) capable of controlling the display panel to display an image.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments.

### Industrial Applicability

The embodiment may be adopted in the field of displays that display images or information. Embodiments may be adopted in the field of displays that display images or information using a semiconductor light emitting device. The semiconductor light emitting device may be a micro-level semiconductor light emitting device or a nano-level semiconductor light emitting device.

For example, embodiments may be adopted for TVs, signage, mobile terminals such as mobile phones or smart phones, laptops or computer displays such as desktops, head-up displays (HUDs) for automobiles, backlight units for displays, displays for VR, AR or MR (mixed reality), and light sources.

1. A semiconductor light emitting device, comprising:
a light emitting layer;
a first electrode below the light emitting layer;
a second electrode on the light emitting layer; and
a passivation layer surrounding the light emitting layer;
wherein a size of the first electrode is larger than a size of the light emitting layer.

2. The semiconductor light emitting device according to claim 1, wherein the first electrode comprises a protrusion portion protruding outward from a side part of the light emitting layer.

3. The semiconductor light emitting device according to claim 1, wherein the first electrode comprising:
an ohmic contact layer below the light emitting layer;
a reflection layer below the light emitting layer; and
a magnetic layer below the reflection layer.

4. The semiconductor light emitting device according to claim 3, wherein at least one layer of the ohmic contact layer, the reflection layer or the magnetic layer protrudes outward from the side part of the light emitting layer.

5. The semiconductor light emitting device according to claim 3, wherein at least one of the ohmic contact layer, the reflection layer or the magnetic layer protrudes outward from the side part of the passivation layer.

6. The semiconductor light emitting device according to claim 3, wherein an upper surface of the ohmic contact layer is in contact with a lower surface of the passivation layer.

7. The semiconductor light emitting device according to claim 3, wherein an outer sides of each of the ohmic contact layer, the reflection layer, and the magnetic layer are disposed on a same vertical line.

8. The semiconductor light emitting device according to claim 3, wherein a lower surface of the light emitting layer has a first area and a second area surrounding the first area,
wherein the ohmic contact layer is in contact with the first area, and
wherein the reflection layer is in contact with the second area.

9. The semiconductor light emitting device according to claim 3, wherein a lower surface of the light emitting layer has a first area and a second area surrounding the first area,
wherein the reflection layer is in contact with the first area,
wherein the ohmic contact layer is in contact with the second area.

10. The semiconductor light emitting device according to claim 3, comprising a metal oxide layer surrounding the first electrode.

11. The semiconductor light emitting device according to claim 10, wherein the metal oxide layer is disposed below the magnetic layer and on sides of each of the ohmic contact layer, the reflection layer, and the magnetic layer.

12. The semiconductor light emitting device according to claim 1, wherein an upper surface of the light emitting layer has a first area and a second area surrounding the first area,
wherein the passivation layer comprising a first passivation layer on the first area; and a second passivation layer on the second area,
wherein a thickness of the first passivation layer is smaller than a thickness of the second passivation layer.

13. The semiconductor light emitting device according to claim 12, wherein the thickness of the first passivation layer is less than ½ of the thickness of the second passivation layer.

14. A display device, comprising:
a backplane substrate having an assembly hole;
a semiconductor light emitting device in the assembly hole;
a connection electrode on a side of the semiconductor light emitting device;
an insulating layer in the assembly hole;
a first electrode wiring connected to an upper side of the connection electrode; and
a second electrode wiring connected to an upper side of the semiconductor light emitting device;
wherein the semiconductor light emitting device is a semiconductor light emitting device according to claim 1.

15. A display device, comprising:
a backplane substrate having the first assembly wiring, the second assembly wiring, and the assembly hole on the first assembly wiring and the second assembly wiring;
a semiconductor light emitting device in the assembly hole;
a connection electrode on a side of the semiconductor light emitting device;
an insulating layer in the assembly hole; and
an electrode wiring connected to an upper side of the semiconductor light emitting device;
wherein at least one assembly wiring of the first assembly wiring or the second assembly wiring is connected to a lower side of the connection electrode, and
wherein the semiconductor light emitting device is a semiconductor light emitting device according to claim 1.

16. The semiconductor light emitting device according to claim 3, wherein the first electrode further comprises at least one of an electrode layer, an antioxidation layer, or an adhesive layer.

17. The semiconductor light emitting device according claim 3, wherein the light emitting layer comprises:
at least one first conductivity semiconductor layer,
an active layer disposed on the first conductivity semiconductor layer, and
at least one second conductivity semiconductor layer disposed on the active layer,
wherein the ohmic contact layer is in contact with the lower surface of the first conductive semiconductor layer.

18. The display device, according to claim 14, further comprising a fixed insulating layer disposed between the semiconductor light emitting device and the first insulating layer, and
wherein the first insulating layer has a shape corresponding to the shape of the semiconductor light emitting device.

19. The display device, according to claim 14, wherein the fixed insulating layer has the shape corresponding to a shape of the first electrode of the semiconductor light emitting device.

20. The display device, according to claim 14, wherein a length of the protrusion portion is smaller than a separation distance between an outer side of the semiconductor light emitting device and an inner side of the assembly hole.
